(19) United States
(12) Patent Application Publication
(10) Pub. No.: US 2008/0310137 A1
(43) Pub. Date: Dec. 18, 2008

(54) Function Element, Method For Manufacturing The Function Element, Electronic Device Equipped With The Function Element, And Method For Manufacturing The Electronic Device

(76) Inventor: Kaoru Soeta, Tokyo (JP)

Correspondence Address: BRINKS HOFER GILSON & LIONE, P.O. BOX 10395, CHICAGO, IL, 60610, US

(21) Appl. No.: 11/574,298

(22) PCT Filed: Aug. 10, 2005
(86) PCT No.: PCT/JP2005/014639

§ 371 Date: Feb. 26, 2007

(30) Foreign Application Priority Data
Aug. 26, 2004 (JP) 2004-247037

(51) Int. Cl. H05K 7/02; H05K 3/00

(52) U.S. Cl. 361/807; 29/829

(57) ABSTRACT

In the present invention, a microphone body 20 has recesses 20b. Bases 22 included in terminal portions are embedded in the recesses so that element-side terminals 23 fixed to the bases are electrically connected to the microphone body 20. The element-side terminals 23 are resiliently deformable terminals. Thus, the element-side terminals 23 are resiliently deformed to become conductively connected to the microphone body 20. This eliminates the need for joining the element-side terminals 23 to the microphone body 20 by soldering or the like, whereby the microphone body 20 can be properly protected from influence of heat. In addition, the terminal portions can be readily and properly attached to the element body by automatic mounting.

### TECHNICAL FIELD

The present invention relates to function elements, such as speakers and microphones in portable telephones, and particularly, to a function element that allows terminal portions to be attached readily and properly to the function element by automatic mounting and that can be properly protected from influence of heat. The present invention also relates to a method for manufacturing such a function element, to an electronic device equipped with such a function element, and to a method for manufacturing such an electronic device.

### BACKGROUND ART

Japanese Unexamined Patent Application Publication No. 10-262294 discloses an invention that relates to a compact microphone assembly that employs conductive rubber contacts.

As shown in FIG. 1 in this document, the compact microphone assembly includes a compact capacitor-microphone body 11, conductive rubber contacts 13, 14, and a vibration-proof molded rubber member 12.

It is written in paragraph [0014] in this publication that “the conductive rubber contacts 13, 14 are formed by molding an uncured conductive rubber compound into a predetermined shape on an electrode surface of the compact capacitor-microphone body 11 and then curing the compound so that the compound is self-adhered to the electrode surface”.

A microphone installed in, for example, a portable telephone contains a built-in electromagnetic coil or the like, and the thermal stability of the microphone itself is not very high. For this reason, when setting a terminal in the microphone, it is not preferable to join the terminal to the microphone by, for example, soldering since the heat can have negative influence on the microphone body.

Based on the fact that an uncured conductive rubber compound is molded on the electrode surface of the compact capacitor-microphone body 11 before being cured, as written in the aforementioned document, it is assumed that the conductive rubber contacts 13, 14 are joined to the compact capacitor-microphone body 11 by application of heat.

Therefore, with the terminal-forming technique discussed in the aforementioned document, the heat applied for joining the conductive rubber contacts 13, 14 to the compact capacitor-microphone body 11 can possibly damage the compact capacitor-microphone body 11.

FIG. 17 is a partial cross-sectional view showing a state where a conventional microphone is installed within a frame of an electronic device, such as a portable telephone.

As shown in FIG. 17, a microphone body 1 is provided with terminal portions 2 on a lower surface thereof. The terminal portions 2 are joined to the microphone body 1 by soldering. Consequently, as described above, this configuration is not preferable since the heat applied for soldering the terminal portions 2 to the microphone body 1 can possibly damage the microphone body 1.

Furthermore, in FIG. 17, the terminal portions 2 are attached manually to the microphone body 1. In view of achieving mass production, it is preferable that the terminal portions 2 can be attached to the microphone body 1 by automatic mounting. In Patent Document 1, it is not clear whether or not the conductive rubber contacts 13, 14 can be attached to the compact capacitor-microphone body 11 by automatic mounting.

Furthermore, in FIG. 17, since the microphone body 1 is press-fitted manually to the frame 3 of the portable telephone, this process for fitting the microphone body 1 into the frame 3 is time-consuming.

It is therefore an object of the present invention to solve the aforementioned conventional problems by providing a function element that allows terminal portions to be attached readily and properly to the function element by automatic mounting and that can be properly protected from influence of heat, a method for manufacturing such a function element, an electronic device equipped with such a function element, and a method for manufacturing such an electronic device.

### DISCLOSURE OF INVENTION

### Problems to be Solved by the Invention

The present invention provides a function element that includes an element body and a terminal portion. The element body has a recess. The terminal portion includes a base, an element-side terminal fixed to the base and electrically connectable to the element body, and an electronic-device-side terminal fixed to the base and electrically connectable to an electronic device. At least one of the element-side terminal and the electronic-device-side terminal is a resiliently deformable terminal. The base is embedded in the recess so that the element-side terminal is electrically connected to the element body.

As described above, in the present invention, the element body has a recess, and the base included in the terminal portion is embedded in the recess so that the element-side terminal is electrically connected to the element body. This eliminates the need for joining the element-side terminal to the element body by soldering or the like, whereby the element body can be properly protected from influence of heat. In addition, the terminal portion can be readily and properly attached to the element body by automatic mounting.

In the present invention, in a state where the base is embedded in the recess, the base has an exposed surface which is a surface that is exposed on an outer surface of the element body, an insertion surface which is a surface that is positioned opposite to the exposed surface, and a side surface which is a surface that connects the insertion surface and the exposed surface. Based on this state, the element-side terminal is preferably provided on the insertion surface, and the electronic-device-side terminal is preferably provided on the exposed surface. Thus, the terminal portion can be given a simple structure, and the base can be appropriately embedded in the recess.

As mentioned above, in the present invention, although at least one of the element-side terminal and the electronic-device-side terminal is a resiliently deformable terminal, it is preferable that the element-side terminal be the resiliently deformable terminal. This allows the element body and the element-side terminal to be electrically connected to each other properly and readily.

On the other hand, in a case where the electronic-device-side terminal is made resiliently deformable, the electronic-device-side terminal and the electronic device can be properly made in contact with each other regardless of whether there are irregularities on the surface of electronic device to which the electronic-device-side terminal is to be joined. In addition, the electronic-device-side terminal can be electrically connected to an electronic-device-side terminal without having to join the electronic-device-side terminal to the electronic device by soldering or the like.

Furthermore, in the present invention, the element-side terminal and the electronic-device-side terminal may both be resiliently deformable terminals.

Furthermore, in the present invention, the resiliently deformable terminal preferably has a spiral shape such that the center of the spiral protrudes away from the base. For example, if the element-side terminal is the resiliently deformable terminal, the element body and the element-side terminal can be electrically connected to each other readily and properly.

Furthermore, in the present invention, in a state where the base is embedded in the recess, the base has an exposed surface which is a surface that is exposed on an outer surface of the element body, an insertion surface which is a surface that is positioned opposite to the exposed surface, and a side surface which is a surface that connects the insertion surface and the exposed surface. Based on this state, the insertion surface and the side surface preferably have a sloped surface therebetween. In an area where the sloped surface is provided, a width of the base increases gradually from the insertion surface towards the exposed surface. Accordingly, the base can be easily inserted into the recess of the element body.

Furthermore, in the present invention, the base preferably has a through hole that extends between a surface of the base on which the element-side terminal is provided and another surface of the base on which the electronic-device-side terminal is provided. Moreover, the element-side terminal and the electronic-device-side terminal are preferably electrically connected to each other through a conductive member provided within the through hole. Accordingly, the element-side terminal and the electronic-device-side terminal can be electrically connected to each other properly and readily.

Furthermore, in the present invention, it is preferable that the element-side terminal and the electronic-device-side terminal respectively include a plurality of element-side terminals and a plurality of electronic-device-side terminals that are provided on the same base. In this case, the base is embedded in the recess so that the plurality of element-side terminals is electrically connected to the element body. Accordingly, the plurality of element-side terminals can be readily electrically connected to the function element.

Furthermore, in the present invention, it is preferable that the base be press-fitted to the recess. This allows the base to be held firmly within the recess of the element body without requiring a filling material, such as resin.

In the present invention, the function element is preferably a speaker or a microphone.

The present invention provides an electronic device having an electrode that is electrically connected to the electronic-device-side terminal of the aforementioned function element. In this invention, the terminal portion can be attached to the function element by automatic mounting, and moreover, the function element can be installed into the electronic device also by automatic mounting.

In the present invention, it is preferable that the electronic-device-side terminal be the resiliently deformable terminal. In that case, the electronic-device-side terminal is pressed against the electrode of the electronic device so as to be electrically connected to the electrode. According to this structure, it is not necessary to join the electronic-device-side terminal and the electrode of the electronic device together by soldering or the like, and the electrical connection between the electronic-device-side terminal and the electrode can be properly achieved with a simple structure.

Furthermore, in the present invention, the electronic device is preferably a portable telephone. Accordingly, the present invention allows for automatic mounting of a function element to a compact electronic device.

Furthermore, the present invention provides a method for manufacturing a function element that includes an element body and a terminal portion. The method includes forming a recess in the element body; setting an element-side terminal on an insertion surface of a base included in the terminal portion and setting an electronic-device-side terminal on a surface of the base that is opposite to the insertion surface, the insertion surface facing in a direction in which the base is to be inserted into the recess, at least one of the element-side terminal and the electronic-device-side terminal being a resiliently deformable terminal; and embedding the base into the recess with the insertion surface facing the recess so as to electrically connect the element-side terminal to the element body.

As described above, in the present invention, the base included in the terminal portion is embedded in the recess of the element body so that the element-side terminal is electrically connected to the function element. Thus, the terminal portion can be readily and properly attached to the function element by automatic mounting.

Furthermore, in the present invention, although at least one of the element-side terminal and the electronic-device-side terminal is a resiliently deformable terminal, it is preferable that the element-side terminal be the resiliently deformable terminal or that both the element-side terminal and the electronic-device-side terminal be resiliently deformable terminals. In that case, the element-side terminal is resiliently deformed so that the element-side terminal is electrically connected to the element body. Thus, the element-side terminal and the element body can be electrically connected to each other readily and properly.

Furthermore, in the present invention, it is preferable that the base be press-fitted to the recess. This allows the terminal portion to be held firmly within the recess of the element body.

Furthermore, in the present invention, it is preferable that a plurality of the element-side terminals be set on the insertion surface of a substrate having a plurality of the bases integrated therein, and that a plurality of the electronic-device-side terminals be set on the surface of the substrate that is opposite to the insertion surface. In that case, the substrate is subsequently cut into the individual bases. Accordingly, a plurality of terminal portions can be formed at the same time.

Furthermore, in the present invention, it is preferable that the method further include forming grooves along cutting lines in the insertion surface of the substrate so that when the substrate is cut into the individual bases, sloped surfaces are formed between the insertion surfaces and side surfaces of the bases, the side surfaces connecting the insertion surfaces with the surfaces of the bases that are opposite to the insertion surfaces, the sloped surfaces being formed such that a width of each base increases gradually from the insertion surface thereof towards the surface opposite to the insertion surface. Forming the sloped surfaces on each base facilitates the process for inserting the base into the recess of the element body. Consequently, this contributes to a higher yield rate for the attachment process of the bases.

Furthermore, in the present invention, the resiliently deformable terminal included in the at least one of the element-side terminal and the electronic-device-side terminal preferably includes a plurality of resiliently deformable terminals, the plurality of resiliently deformable terminals being attached to a sheet member. Moreover, it is preferable that the sheet member be joined to the substrate, and that the substrate and the sheet member be subsequently cut together into the individual bases.

The resiliently deformable terminals are electroformed by, for example, photolithography. Preferably, after these resiliently deformable terminals are formed, these terminals are fixed to the sheet member to prevent the terminals from being dismantled into pieces. The sheet member is then joined to the substrate before proceeding to the cutting step so that the resiliently deformable terminals can be attached to the bases readily and properly.

Furthermore, in the present invention, the substrate may be cut into the individual bases after the sheet member is joined to the substrate and removed therefrom.

Furthermore, in the present invention, the method may further include storing the terminal portion into a carrier tape, the terminal portion having the element-side terminal and the electronic-device-side terminal attached to the base of the terminal portion; extracting the terminal portion from the carrier tape while holding the terminal portion with a carrying member; and inserting the terminal portion into the recess of the element body. This ensures that the terminal portion that is extremely small in size can be properly held and inserted into the recess of the function element, thereby contributing to a higher yield rate in an automated system.

Furthermore, the present invention provides a method for manufacturing an electronic device. The method includes electrically connecting the electronic-device-side terminal of the function element manufactured on the basis of the method set forth in claim 15 to an electrode of the electronic device. According to this invention, the terminal portion can be attached to the function element by automatic mounting, and moreover, the function element can be installed into the electronic device also by automatic mounting.

In the present invention, it is preferable that the electronic-device-side terminal be the resiliently deformable terminal. In that case, the electronic-device-side terminal is pressed against the electrode of the electronic device so as to be electrically connected to the electrode. Accordingly, it is not necessary to join the electronic-device-side terminal and the electrode of the electronic device together by soldering or the like, and the electrical connection between the electronic-device-side terminal and the electrode can be properly achieved with a simple structure.

Alternatively, in the present invention, the electronic-device-side terminal and the electrode of the electronic device may be joined to each other by soldering. Since the terminal portion includes the base in this invention, the heat applied for soldering the electronic-device-side terminal to the electrode of the electronic device will not be directly transmitted to the element body. Consequently, this reduces the risk of damages on the element body caused by heat.

In the present invention, the element body has a recess, and the base included in the terminal portion is embedded in the recess so that the element-side terminal fixed to the base is electrically connected to the element body. This eliminates the need for joining the element-side terminal to the element body by soldering or the like, whereby the element body can be properly protected from influence of heat. In addition, the terminal portion can be readily and properly attached to the element body by automatic mounting.

In the present invention, although at least one of the element-side terminal and the electronic-device-side terminal is a resiliently deformable terminal, it is preferable that the element-side terminal be the resiliently deformable terminal. This allows the element body and the element-side terminal to be electrically connected to each other properly and readily.

On the other hand, in a case where the electronic-device-side terminal is made resiliently deformable, the electronic-device-side terminal and the electronic device can be properly made in contact with each other regardless of whether there are irregularities on the surface of electronic device to which the electronic-device-side terminal is to be joined. In addition, the electronic-device-side terminal can be electrically connected to an electronic-device-side terminal without having to join the electronic-device-side terminal to the electronic device by soldering or the like.

### BEST MODE FOR CARRYING OUT THE INVENTION

FIG. 1 is a partial plan view of a portable telephone. FIG. 2 is a partial plan view of the portable telephone in a state where an upper casing of the portable telephone is removed. FIG. 3 is a partial cross-sectional view of the portable telephone taken along line I-I in FIG. 1, as viewed in a direction indicated by an arrow. FIG. 4 is a cross-sectional view showing an enlarged portion of the partial cross-sectional view in FIG. 3, and illustrates a structure of a function element (microphone) according to a first embodiment of the present invention. FIG. 5 is an enlarged perspective view showing a terminal portion according to the present invention. FIG. 6 is a cross-sectional view showing an enlarged portion of the partial cross-sectional view in FIG. 3, and illustrates a structure of a function element (microphone) according to a second embodiment of the present invention. FIG. 7 is a cross-sectional view showing an enlarged portion of the partial cross-sectional view in FIG. 3, and illustrates a structure of a function element (microphone) according to a third embodiment of the present invention. FIG. 8 is a cross-sectional view showing an enlarged portion of the partial cross-sectional view in FIG. 3, and illustrates a structure of a function element (microphone) according to a fourth embodiment of the present invention. FIG. 9 is a cross-sectional view showing an enlarged portion of the partial cross-sectional view in FIG. 3, and illustrates a structure of a function element (microphone) according to a fifth embodiment of the present invention.

Referring to FIG. 1, a portable telephone 10 includes a speaker 14, a display portion 12, various kinds of buttons 13, and a microphone 11.

Referring to FIG. 3, the portable telephone 10 has an upper casing 15, a frame 16 in which various kinds of components are installed, and a lower casing, not shown. As shown in FIGS. 2 and 3, the frame 16 has the microphone 11 fitted therein. As shown in FIG. 3, the microphone 11 has, for example, two terminal portions 17, 17 protruding from the lower surface thereof. The terminal portions 17, 17 are electrically connected to electrodes on a wiring substrate 18, which is fixed to the frame 16 with screws 19, 19 or the like.

Referring to FIG. 4, the microphone 11 includes a microphone body 20 and the terminal portions 17, 17. The microphone body 20 includes, for example, a diaphragm, a magnetic circuit, and a voice coil. As shown in FIG. 4, a lower surface 20a of the microphone body 20 has two recesses 20b. An X-Y plane extending in a width direction (X direction in the drawing) and a length direction (Y direction in the drawing) of the recesses 20b is substantially rectangular. As shown in FIG. 4, upper surfaces 20b1 of the recesses 20b are provided with electrodes 21, 21 that are electrically connected to the magnetic circuit contained within the microphone body 20. As shown in FIG. 4, the terminal portions 17, 17 are embedded in the recesses 20b. The structure of the terminal portions 17, 17 will be described below.

As shown in FIG. 4, each of the terminal portions 17, 17 includes a base 22, an element-side terminal 23 disposed on the upper surface (insertion surface) 22a of the base 22, and an electronic-device-side terminal 24 disposed on the lower surface (exposed surface) 22b of the base 22.

Each of the bases 22 is composed of an insulative material, such as plastic and resin, and has a substantially rectangular shape as shown in FIGS. 4 and 5. The maximum dimensions of the base 22 in the width direction (X direction) and the length direction (Y direction) are substantially the same as or smaller than the dimensions of the recess 20b in the microphone body 20 shown in FIG. 4 in the width direction (X direction) and the length direction (Y direction), respectively. Furthermore, the dimension of the base 22 in the height direction (Z direction in the drawing) is determined in view of, for example, the distance between the lower surface 20a of the microphone body 20 and the wiring substrate 18, the height of the element-side terminal 23, and the height of the electronic-device-side terminal 24. The bases 22 do not necessary have to be substantially rectangular, and may alternatively be, for example, substantially columnar. In that case, the shape of the recesses 20b is modified in correspondence to the shape of the bases 22.

Referring to FIGS. 4 and 5, each base 22 has sloped surfaces 22d interposed between the upper surface 22a and side surfaces 22c. In an area where the sloped surfaces 22d are provided, the width (and the length) of the base 22 increases gradually from the upper surface 22a towards the lower surface 22b. Thus, the base 22 can be easily inserted into the corresponding recess 20b with the upper surface 22a being an insertion surface.

As shown in FIG. 4, each base 22 has a through hole 25 that extends from the upper surface 22a to the lower surface 22b. In the embodiment shown in FIG. 4, each through hole 25 has a metallic layer 26 of, for example, Cu implanted therein. Thus, the element-side terminal 23 and the electronic-device-side terminal 24 are electrically connected to each other through the metallic layer 26.

As shown in FIGS. 4 and 5, each element-side terminal 23 is a resiliently deformable terminal that is wound into a spiral. The element-side terminal 23 is electroformed by, for example, photolithography, and has a multilayer structure that includes a layer of a highly-resilient metallic material, such as Ni, and a layer that is highly conductive and durable, such as Au.

As shown in FIGS. 4 and 5, a base section 23a of each element-side terminal 23 is joined to the upper surface 22a of the corresponding base 22 with a conductive adhesive, and the spiral terminal section extends from the base section 23a. The spiral terminal section extends three-dimensionally from a spiral-start end 23b towards a spiral-stop end (spiral center) 23c so as to gradually extend away from the base 22. Thus, the spiral-stop end 23c and its vicinity are the most upward projected portion of the spiral terminal section.

As shown in FIG. 4, similar to the element-side terminals 23, the electronic-device-side terminals 24 are also resiliently deformable terminals that are wound into a spiral.

As shown in FIG. 4, the bases 22 are embedded in the recesses 20b with the element-side terminals 23 facing the electrodes 21 so that the element-side terminals 23 are electrically connected to the electrodes 21 of the microphone body 20. In this case, because the element-side terminals 23 are resiliently deformable terminals, the element-side terminals 23 become resiliently deformed in response to pushing of the bases 22 towards the electrodes 21. This increases the contact area between the element-side terminals 23 and the electrodes 21, thereby ensuring a conductive connection between the element-side terminals 23 and the electrodes 21. Giving the element-side terminals 23 resilient deformability allows for a proper conductive connection without having to use solder or conductive adhesive for joining the element-side terminals 23 and the electrodes 21 together. In addition, due to having a three-dimensional structure in which the spiral-stop end 23c and its vicinity are projected, each element-side terminal 23 can come into contact with the corresponding electrode 21 even if the base 22 is not completely pushed into the recess 20b, and can be appropriately resiliently deformed so that the element-side terminal 23 and the electrode 21 can be conductively connected to each other.

In the present invention, each base 22 is preferably press-fitted into the corresponding recess 20b. Thus, when the base 22 is inserted into the recess 20b, the base 22 can be properly retained in the recess 20b without having to use, for example, a filling material, such as resin. Accordingly, the conductive connection between the element-side terminals 23 and the electrodes 21 can be properly achieved with a simple structure.

As shown in FIG. 4, the electronic-device-side terminals 24 are spiral-shaped resiliently deformable terminals like the element-side terminals 23. Thus, when the electronic-device-side terminals 24 are pressed against electrodes 27 on the wiring substrate 18, the electronic-device-side terminals 24 become resiliently deformed. This increases the contact area between the electronic-device-side terminals 24 and the electrodes 27, thereby ensuring a conductive connection without having to use solder or conductive adhesive. Furthermore, even in a case where the electrode-holding surface of the wiring substrate 18 has irregularities, the electronic-device-side terminals 24 can be properly made in contact with the electrodes 27 on the wiring substrate 18.

In an embodiment shown in FIG. 6, the structure of the electronic-device-side terminals is different from that shown in FIG. 4. In contrast to FIG. 4 in which the electronic-device-side terminals 24 are spiral-shaped resiliently deformable terminals, electronic-device-side terminals 30 (which are sometimes referred to as bumps 30 hereinafter) in FIG. 6 are defined by bumps. For example, each of the bumps 30 is a soldered layer. Each bump 30 is formed by soldering solder paste to the lower surface 22b of the corresponding base 22 by, for example, screen printing. Subsequently, heat is applied to melt the bump 30 so that the bump 30 and the corresponding electrode 27 on the wiring substrate 18 are joined to each other (i.e. so-called reflow soldering).

In the case of the embodiment shown in FIG. 6, since heat is applied to melt the solder, the embodiment is preferably directed to a capacitor-type microphone in which the microphone body 20 is composed basically of a highly heat-resistant material, such as silicon. In FIG. 6, since the bases 22 are provided as components of the terminal portions 17, 17, the heat is not directly transmitted to the microphone body 20. This implies that the influence of soldering heat on the microphone body 20 can be reduced.

In an embodiment shown in FIG. 7, the structure of the element-side terminals is different from that shown in FIG. 4. In contrast to FIG. 4 in which the element-side terminals 23 are spiral-shaped resiliently deformable terminals, the embodiment shown in FIG. 7 is provided with flat-plate-like element-side terminals 35 formed on the upper surfaces 22a of the bases 22 by plating. The element-side terminals 35 are not resiliently deformable as in FIG. 4.

In the embodiment shown in FIG. 7, the bases 22 are pushed into the recesses 20b of the microphone body 20 until the element-side terminals 35 come into contact with the electrodes 21 of the microphone body 20. Thus, the element-side terminals 35 and the electrodes 21 are conductively connected to each other. Because the bases 22 are embedded in the recesses 20b of the microphone body 20 in the embodiment shown in FIG. 7, the element-side terminals 35 and the electrodes 21 can be conductively connected to each other without having to join the element-side terminals 35 and the electrodes 21 together by, for example, soldering.

In an embodiment shown in FIG. 8, an inner side surface 25a of each through hole 25 is provided with a conductor 40, which is formed to a predetermined thickness along the inner side surface 25a by electroless plating. The through hole 25 is then filled with a sealing material 41, such as resin. Thus, the element-side terminals 35 and the electronic-device-side terminals 30 are conductively connected to each other through the conductors 40.

In an embodiment shown in FIG. 9, a pair of element-side terminals 23, 23 and a pair of electronic-device-side terminals 30, 30 are all provided on a single base 45. In the embodiments shown in FIGS. 4 to 8, the recesses 20b and the terminal portions 17 embedded in the recesses 20b are provided as many as the number of electrodes 21 provided in the microphone body 20. In contrast, in FIG. 9, a plurality of electrodes 21, 21 are formed on an upper surface 46a of a recess 46 in the microphone body 20, and the plurality of element-side terminals 23 and the plurality of electronic-device-side terminals 30 are provided on the base 45 embedded in the recess 46. This eliminates the need for providing the terminal portions 17 as many as the number of electrodes 21, thereby reducing the process for embedding the base 45 into the recess 46 as well as shortening the time required for manufacturing the terminal portions 17. In this invention, it is preferable that a single base 45 be provided for a single microphone body 20, and that the base 45 be provided with element-side terminals 23 and electronic-device-side terminals 30 as many as the number of all the electrodes 21.

In the present invention, as described in the above embodiments, the microphone body 20 is provided with the recesses 20b, and the bases 22 included in the terminal portions 17 are embedded in these recesses 20b so that the element-side terminals 23 can be electrically connected to the microphone body 20. Consequently, it is not necessary to join the element-side terminals 23 and the microphone body 20 together by, for example, soldering, whereby the microphone body 20 can be properly protected from influence of heat. In addition, according to the present invention, the terminal portions 17 can be readily and properly attached to the microphone body 20 by automatic mounting, which will be described later.

In this invention, as described in the above embodiments, at least one of the set of element-side terminals 23 and the set of electronic-device-side terminals 24 is resiliently deformable. However, it is preferable that the element-side terminals 23 be resiliently deformable terminals so that the element-side terminals 23 can be resiliently deformed within the recesses 20b. Consequently, this can allow the microphone body 20 and the element-side terminals 23 to become electrically connected to each other in an easy and proper fashion.

On the other hand, in a case where the electronic-device-side terminals 24 are made resiliently deformable, the electronic-device-side terminals 24 and the wiring substrate 18 on the electronic-device side can be properly joined to each other regardless of whether there are irregularities on the surface of the wiring substrate 18 to which the electronic-device-side terminals 24 are joined. In addition, the electronic-device-side terminals 24 can be properly made in contact with the electrodes 27 of the wiring substrate 18 without having to solder the electronic-device-side terminals 24 to the wiring substrate 18, thereby ensuring a conductive connection between the electronic-device-side terminals 24 and the electrodes 27.

Furthermore, in the embodiments shown in FIGS. 4 to 9, the element-side terminals 23 are disposed on the upper surfaces 22a, which are insertion surfaces that face in the direction in which the bases 22 are inserted into the recesses 20b, whereas the electronic-device-side terminals 24 are disposed on the lower surfaces (exposed surfaces) 22b that are opposite to the upper surfaces 22a. Alternatively, in a case where, for example, there is a certain gap between the side surfaces 22c of each base 22 and the corresponding recess 20b, the element-side terminal 23 may be formed on the side surfaces 22c. However, it is preferable that the element-side terminals 23 be disposed on the upper surfaces 22a of the bases 22 and that the electronic-device-side terminals 24 be disposed on the lower surfaces 22b since such a configuration can ensure the conductive connection between the element-side terminals 23 and the electrodes 21 of the microphone body 20 and the conductive connection between the electronic-device-side terminals 24 and the electrodes 27 of the wiring substrate 18 with a simple structure. In addition, this configuration prevents the element-side terminals 23 from being damaged in the course of inserting the bases 22 into the recesses 20b.

FIGS. 10 to 15 illustrate a manufacturing process of the microphone 11 shown in FIG. 4, 5, or 6. FIGS. 10 to 13 illustrate a process for fabricating the terminal portions 17 included in the microphone 11. FIG. 10 is a partial perspective view showing a fabricating step of the terminal portions 17. FIG. 11 is a plan view showing an enlarged section of an upper sheet member shown in FIG. 10. FIG. 12 is a partially enlarged cross-sectional view showing a fabricating step of the terminal portions 17 to be performed after the step shown in FIG. 10. FIG. 13 is a partially enlarged cross-sectional view showing a fabricating step of the terminal portions shown in FIG. 6. FIG. 14 is a partial perspective view showing a step for extracting terminal portions held within a carrier tape. FIG. 15 is a partial cross-sectional view showing a step for inserting each terminal portion into one of the recesses of the microphone body. FIG. 16 is a partial perspective view showing a step for installing a microphone obtained after the step shown in FIG. 15 into a portable telephone body.

In the step shown in FIG. 10, three members are prepared. Reference numeral 50 denotes an upper sheet member. The upper sheet member 50 has a plurality of element-side terminals 23. The element-side terminals 23 are resiliently deformable terminals and have a spiral shape as shown in FIG. 5. The element-side terminals 23 are electroformed by photolithography. As shown in FIG. 5, each element-side terminal 23 is formed three-dimensionally such that its spiral-stop end (spiral center) 23c protrudes upward. After forming the element-side terminals 23, an insulating sheet 53 composed of, for example, polyimide is adhered onto the base sections 23a of the element-side terminal 23 by using a conductive adhesive, whereby the element-side terminals 23 are fixed to the insulating sheet 53. As shown in FIG. 10, the insulating sheet 53 has through holes 53a that are provided as many as the number of element-side terminals 23 and have a size that is slightly smaller than the outer circumference of the base sections 23a of the element-side terminals 23. The base section 23a of each element-side terminal 23 is fixed below a periphery section of the corresponding through hole 53a, and the spiral section of the element-side terminal 23 (i.e. the section between the spiral-start end 23b and the spiral-stop end 23c) protrudes upward from within the through hole 53a.

Reference numeral 52 denotes a lower sheet member. The lower sheet member 52 is the same as the upper sheet member 50. Specifically, the lower sheet member 52 is the upper sheet member 50 shown in FIG. 10 in a reversed state.

Reference numeral 51 denotes a substrate. The substrate 51 is constituted by a plurality of integrally molded bases 22. In a subsequent step, the substrate 51 is cut into the plurality of bases 22. As shown in FIG. 10, a plurality of through holes 25 is formed in the substrate 51. Each through hole 25 has a metallic layer 26 of, for example, Cu implanted therein. For example, the metallic layers 26 are implanted by means of a known plating technique.

The metallic layers 26, the element-side terminals 23, and the electronic-device-side terminals 24 are positionally aligned with one another, in the thickness direction. As shown in FIG. 10, an upper surface Sla of the substrate 51, namely, a surface facing the upper sheet member 50, has grooves 54 that are formed along cutting lines by, for example, etching. The grooves 54 are substantially V-shaped in cross section taken in a direction perpendicular to the cutting lines and in the thickness direction. By forming the grooves 54 into a V-shape, the sloped surfaces 22d are formed between the upper surfaces 22a and the side surfaces 22c of the bases 22 when the substrate 51 is cut into the individual bases 22 along the cutting lines (see FIG. 5). The sloped surfaces 22d allow the width of each base 22 to increase gradually from the upper surface 22a towards the lower surface 22b.

Furthermore, as shown in FIG. 10, a lower surface 51b of the substrate 51 also has grooves 55 formed along cutting lines. However, the grooves 55 formed in the lower surface 51b of the substrate 51 may be shallower than the grooves 54 formed in the upper surface 51a. Alternatively, the lower surface 51b of the substrate 51 does not need to be provided with the grooves 55.

Furthermore, referring to FIG. 11, the insulating sheet 53 included in the upper sheet member 50 may have slits 56 formed along the cutting lines. Each of the slits 56 is positionally aligned with a deepest section 54a of the corresponding groove 54 (i.e. the center position of the groove 54). The slits 56 serve as good indicators for indicating the sections to be cut in the subsequent cutting step, whereby the cutting step can be properly implemented.

In a step shown in FIG. 12, the upper sheet member 50 is adhered to the upper surface 51a of the substrate 51 shown in FIG. 10 by means of a conductive adhesive or the like, and the lower sheet member 52 is adhered to the lower surface 51b of the substrate 51 by means of a conductive adhesive or the like. According to this step, the base sections 23a of the element-side terminals 23 are joined to the upper surfaces of the metallic layers 26, and the base sections of the electronic-device-side terminals 24 are joined to the lower surfaces of the metallic layers 26, whereby the element-side terminals 23 and the electronic-device-side terminals 24 are conductively connected to each other through the metallic layers 26. Subsequently, the insulating sheets 53 and the substrate 51 are cut along the cutting lines of the substrate 51. Since the cutting lines are positioned above the deepest sections 54a of the grooves 54, the substrate 51 is cut along the deepest sections 54a in a direction indicated by dotted lines in FIG. 12 (thickness direction). For the cutting, a dicing cutter, for example, is used.

Accordingly, a plurality of the terminal portions 17, having the element-side terminals 23 disposed above the bases 22 and the electronic-device-side terminals 24 disposed below the bases 22 as shown in FIGS. 4 and 5, is formed simultaneously in the same step.

In a case where, for example, the bumps 30 are to be provided on one side of the bases 22 as shown in FIG. 6, only the substrate 51 and the upper sheet member 50 are prepared in the step shown in FIG. 10. Before adhering the substrate 51 and the upper sheet member 50 together, the bumps 30 are preliminarily formed on the lower surface 51b of the substrate 51 by, for example, screen printing. Since the through holes 25 in the substrate 51 have the metallic layers 26 implanted therein, the lower surface 51b of the substrate 51 is substantially flat, which means that the bumps 30 can be readily formed on the lower surface 51b by, for example, screen printing. Subsequently, the substrate 51 and the upper sheet member 50 are adhered to each other by means of a conductive adhesive or the like, and the substrate 51 is then cut into the individual bases 22 using a dicing cutter or the like.

After the cutting of the bases 22 in the steps shown in FIGS. 12 and 13, the insulating sheet(s) 53 is/are left remaining between the bases 22 and the element-side terminals 23 (and between the bases 22 and the electronic-device-side terminals 24). The insulating sheet(s) 53 may remain or be removed if not particularly necessary. As a timing for removing the insulating sheet(s) 53, the insulating sheet(s) 53 is/are preferably removed prior to the cutting step and after the upper sheet member 50 has been adhered to the substrate 51 and the lower sheet member 52 has been adhered to the lower surface of the substrate 51 in the step shown in FIG. 12. Removing the insulating sheet(s) 53 prior to the cutting step eliminates the need for cutting the insulating sheet(s) 53 at the time of the cutting step and also eliminates the need for providing the slits 56 in the corresponding insulating sheet 53 shown in FIG. 11. However, if the slits 56 are to serve as, for example, positioning windows to be used when adhering the upper sheet member 50 onto the substrate 51 instead of as indicators for the cutting sections, it is preferable that the slits 56 be provided regardless of whether or not the insulating sheet(s) 53 is/are to be removed. In that case, for example, the slits 56 used for the positioning are disposed such that the deepest sections 54a of the grooves 54 are viewable through all of the slits 56.

The plurality of terminal portions 17 obtained as a result of the above-described steps is stored in a carrier tape 60 as shown in FIG. 14. The carrier tape 60 includes a tape base material 61 and a removable film 62 that covers the tape base material 61. The tape base material 61 has a plurality of storage chambers 61a arranged at predetermined intervals in the tape unwinding direction. As shown in FIG. 14, the terminal portions 17 are stored within the storage chambers 61a, and the removable film 62 is adhered to the tape base material 61. The terminal portions 17 are preferably stored within the storage chambers 61a with the electronic-device-side terminals 24 facing upward.

The carrier tape 60 shown in FIG. 14 is set in a manufacturing line. While the removable film 62 of the carrier tape 60 is peeled off, a suction unit 63 included in a carrying device (not shown) pulls out each of the terminal portions 17 stored in the storage chambers 61a by suction. While holding the terminal portion 17, the suction unit 63 carries the terminal portion 17 to a terminal-attaching area where a microphone body 20 is placed. For example, the suction unit 63 pulls out each terminal portion 17 by vacuum suction.

Referring to FIG. 15, in the terminal-attaching area, the microphone body 20 is set on the manufacturing line in a manner such that the recesses 20b provided in the lower surface 20a face upward. Each terminal portion 17 held by the suction unit 63 is carried to one of the recesses 20b. As described above, since the terminal portions 17 are stored within the storage chambers 61a of the carrier tape 60 with the electronic-device-side terminals 24 facing upward, each terminal portion 17 is carried while the electronic-device-side terminal 24 thereof is held by the suction unit 63.

In order to conductively connect the electrode 21 in the recess 20b to the element-side terminal 23, the terminal portion 17 must be inserted into the recess 20b with the element-side terminal 23 as being the leading end. Since the electronic-device-side terminal 24 is being held as shown in FIG. 15, the element-side terminal 23 in a free state (which is not held by the suction unit 63) can be directly inserted into the recess 20b as a leading end. In this case, when the terminal portion 17 is being inserted into the recess 20b, the holding force of the suction unit 63 may be released and a separately provided designated pushing member may be used to push the terminal portion 17 into the recess 20b. However, it is more preferable that the suction unit 63 be used to push the terminal portion 17 into the recess 20b. This is because the same unit can be used to both carry the terminal portion 17 from the carrier tape 60 and to insert the terminal portion 17 into the recess 20b, which contributes to simplified manufacturing equipment and to a shorter manufacturing time.

As shown in FIG. 15, the side surfaces 22c and the insertion surface 22a (same as the upper surface 22a shown in FIG. 4) that faces in the direction in which the base 22 included in the terminal portion 17 is inserted into the recess 20b have the sloped surfaces 22d therebetween, which allow the width to decrease gradually in the direction of insertion. Therefore, when the suction unit 63 pushes the terminal portion 17 into the recess 20b, even if the base 22 abuts on edges 20b2 of the recess 20b (i.e. edges between the lower surface 20a of the microphone body 20 and the side surfaces of the recess 20b), the base 22 can still enter the recess 20b by sliding with the sloped surfaces 22d of the base 22. Accordingly, the terminal portion 17 can be smoothly inserted into the recess 20b.

In the present invention, the terminal portion 17 is preferably press-fitted into the recess 20b. This allows the terminal portion 17 to be held firmly within the recess 20b without requiring a filling material, such as resin, in the recess 20b.

The terminal portion 17 shown in FIG. 15 is pushed into the recess 20b until the element-side terminal 23 at least abuts on the electrode 21 of the microphone body 20. Because the element-side terminal 23 is a resiliently deformable terminal, the element-side terminal 23 becomes more resiliently deformed as the amount of insertion of the terminal portion 17 increases. This increases the contact area between the element-side terminal 23 and the electrode 21, thereby ensuring a conductive connection between the element-side terminal 23 and the electrode 21.

Accordingly, in the present invention, the terminal portions 17 can be attached to the microphone body 20 by automatic mounting. In addition, the conductive connection between the element-side terminals 23 and the electrodes 21 can be readily and properly achieved without the use of solder, which requires heat for joining the terminal portions 17 and the microphone body 20 together.

The terminal portions shown in FIGS. 6 to 8 can be similarly attached to the microphone body 20 using the same technique described with reference to FIGS. 14 and 15. Furthermore, like the terminal portion shown in FIG. 9, if a plurality of element-side terminals 23 and a plurality of electronic-device-side terminals 24 are to be provided on a single base 45, the base 45 can be given a large size. Especially in a case where the electronic-device-side terminals 24 are not disposed in a central section 45a of the base 45 as in FIG. 9, the suction unit 63 can pull the central section 45a by suction and insert the terminal portion into the recess 46 of the microphone body 20. Due to its large size, the base 45 can be pulled by suction and be carried easily. Moreover, since the suction unit 63 pulls the central section 45a of the base 45 by suction, which is where electronic-device-side terminals 24 are not disposed, the properties of the electronic-device-side terminals 24 are less likely to change in response to the suction force of the suction unit 63 or the pushing force applied towards the recess 46, as compared to a case where each electronic-device-side terminal 24 is pulled by suction and is directly pushed into the recess 46. Furthermore, since the suction unit 63 can pull the central section 45a of the base 45 by suction, the terminal portion can be carried to the recess 46 of the microphone body 20 in a well-balanced manner without causing the base 45 to tilt.

In a step shown in FIG. 16, a microphone 11 having the terminal portions 17 obtained as a result of the step shown in FIG. 15 is installed into an installation hole 16a provided in the frame 16 of a portable telephone. Moreover, the wiring substrate 18 is placed on the underside of the frame 16 so that the electronic-device-side terminals 24 of the microphone 11 and the electrodes 27, 27 on the wiring substrate 18 are made in contact with each other. Thus, the electronic-device-side terminals 24 and the electrodes 27 become conductively connected to each other. Subsequently, the screws 19 shown in FIG. 3 are used to fix the wiring substrate 18 onto the frame 16.

In the assembly step shown in FIG. 16, after press-fitting the microphone 11 into the installation hole 16a of the frame, for example, the electrodes 27 on the wiring substrate 18 and the electronic-device-side terminals 24 of the microphone 11 are pressed against each other. Thus, the resiliently deformable electronic-device-side terminals 24 become resiliently deformed, whereby the contact area between the electronic-device-side terminals 24 and the electrodes 27 increases. Accordingly, this ensures the conductive connection between the electronic-device-side terminals 24 and the electrodes 27 without having to join the electronic-device-side terminals 24 and the electrodes 27 together by, for example, soldering.

On the other hand, if the electronic-device-side terminals are defined by bumps 30 as in FIG. 6, the bumps 30 and the electrodes 27 on the wiring substrate 18 may first be joined together by reflow soldering, and the microphone 11 may then be inserted into the installation hole 16a of the frame 16.

In the step shown in FIG. 16, the microphone 11 and the wiring substrate 18 can be combined with the frame 16 by automatic mounting.

Although the structures of the terminal portions 17 of the microphone 11 and the method for manufacturing the microphone 11 have been described above, the present invention can also be applied to the speaker 14.

Furthermore, although the electronic device is defined by a portable telephone 10 as an example, the electronic device is not limited to a portable telephone. The present invention can be applied to other types of electronic devices. In particular, the present invention allows for automatic mounting of function elements, such as microphones and speakers, to compact electronic devices, such as portable telephones, so that the productivity rate can be increased significantly in comparison to the conventional art.

### INDUSTRIAL APPLICABILITY

The present invention relates to function elements, such as speakers and microphones in portable telephones. In particular, the present invention advantageously provides a function element that allows terminal portions to be attached readily and properly to the function element by automatic mounting and that can be properly protected from influence of heat. The present invention also provides a method for manufacturing such a function element, an electronic device equipped with such a function element, and a method for manufacturing such an electronic device.

### BRIEF DESCRIPTION OF THE DRAWINGS

FIG. 1 is a partial plan view of a portable telephone.

FIG. 2 is a partial plan view of the portable telephone in a state where an upper casing of the portable telephone is removed.

FIG. 3 is a partial cross-sectional view of the portable telephone taken along line I-I in FIG. 1, as viewed in a direction indicated by an arrow.

FIG. 4 is a cross-sectional view showing an enlarged portion of the partial cross-sectional view in FIG. 3, and illustrates a structure of a function element (microphone) according to a first embodiment of the present invention.

FIG. 5 is an enlarged perspective view showing a terminal portion according to the present invention.

FIG. 6 is a cross-sectional view showing an enlarged portion of the partial cross-sectional view in FIG. 3, and illustrates a structure of a function element (microphone) according to a second embodiment of the present invention.

FIG. 7 is a cross-sectional view showing an enlarged portion of the partial cross-sectional view in FIG. 3, and illustrates a structure of a function element (microphone) according to a third embodiment of the present invention.

FIG. 8 is a cross-sectional view showing an enlarged portion of the partial cross-sectional view in FIG. 3, and illustrates a structure of a function element (microphone) according to a fourth embodiment of the present invention.

FIG. 9 is a cross-sectional view showing an enlarged portion of the partial cross-sectional view in FIG. 3, and illustrates a structure of a function element (microphone) according to a fifth embodiment of the present invention.

FIG. 10 is a partial perspective view showing a fabricating step of terminal portions 17 shown in FIG. 4.

FIG. 11 is a plan view showing an enlarged section of an upper sheet member shown in FIG. 10.

FIG. 12 is a partially enlarged cross-sectional view showing a fabricating step of the terminal portions 17 to be performed after the step shown in FIG. 10.

FIG. 13 is a partially enlarged cross-sectional view showing a fabricating step of terminal portions shown in FIG. 6.

FIG. 14 is a partial perspective view showing a step for extracting terminal portions held within a carrier tape.

FIG. 15 is a partial cross-sectional view showing a step for inserting a terminal portion into a recess of a microphone body.

FIG. 16 is a partial perspective view showing a step for installing a microphone obtained after the step shown in FIG. 15 into a portable telephone body.

FIG. 17 is a partial cross-sectional view showing a state where a conventional microphone is installed within a frame of an electronic device, such as a portable telephone.

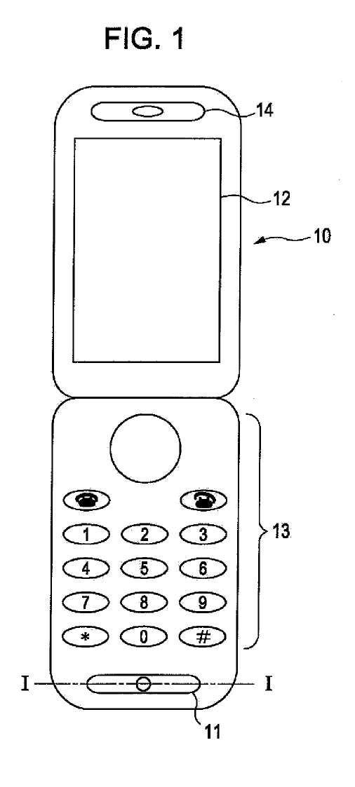

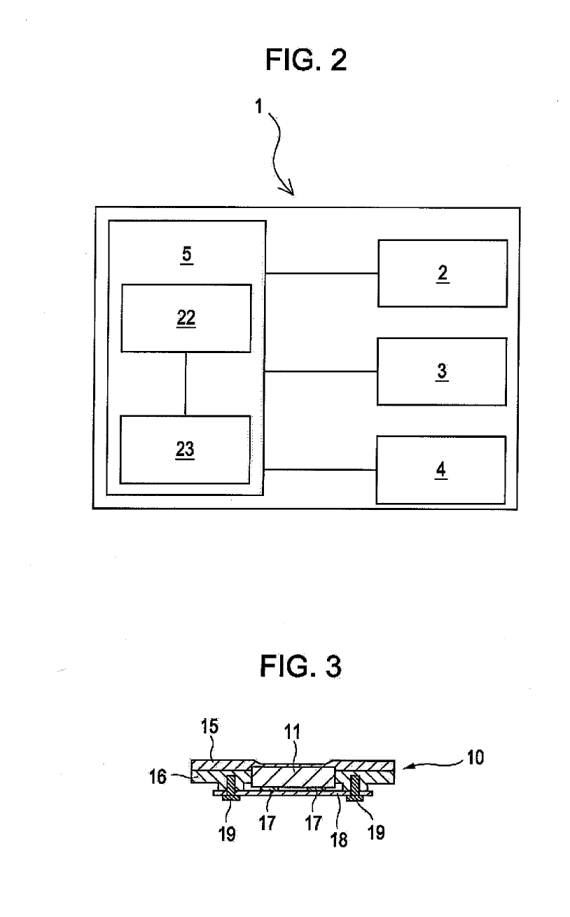

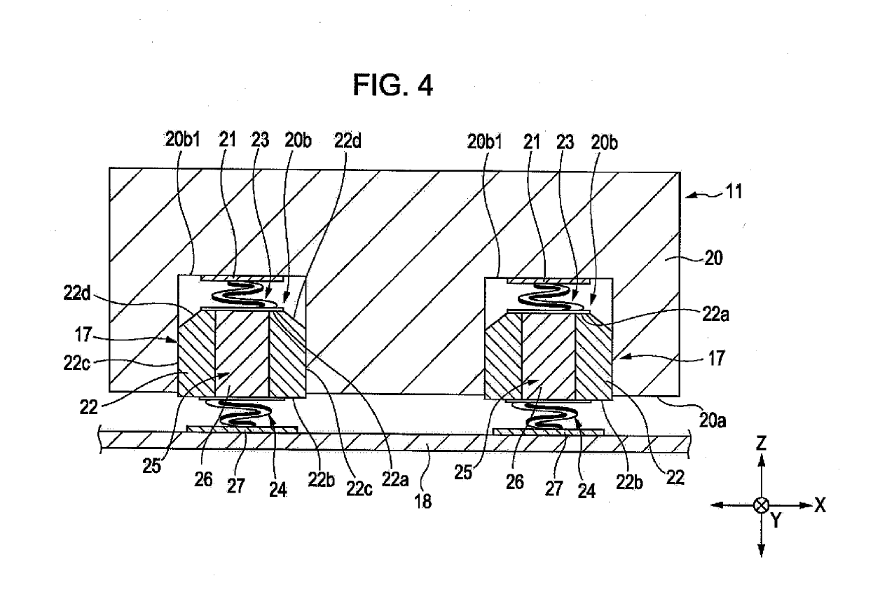

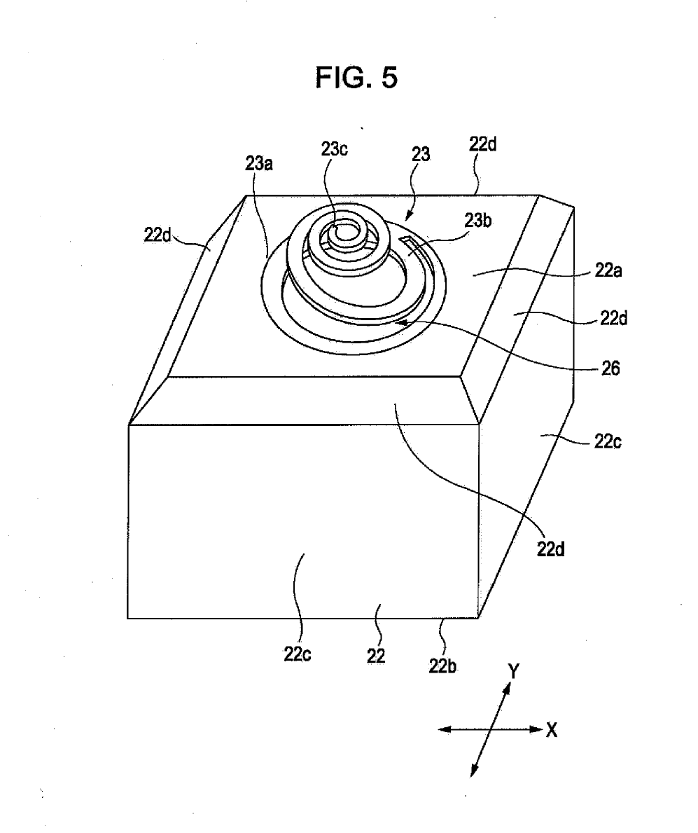

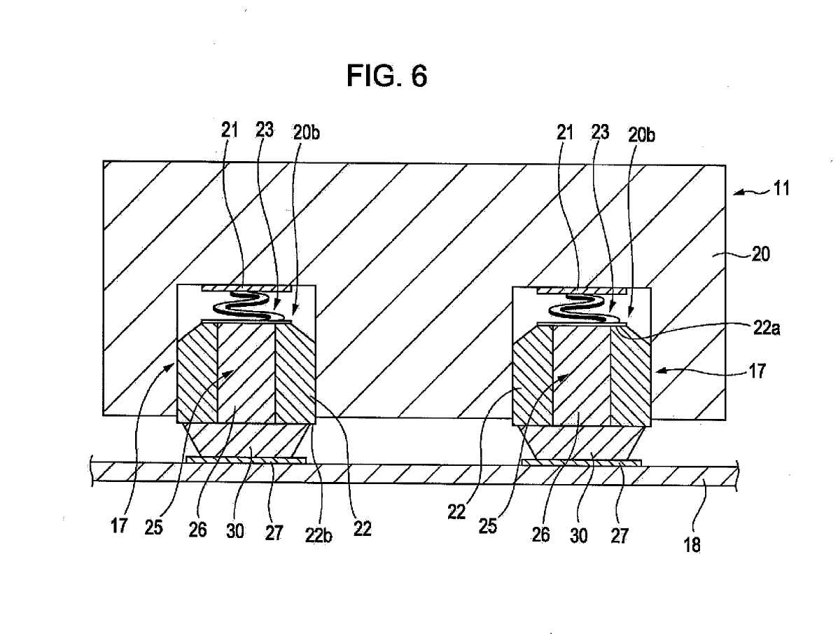

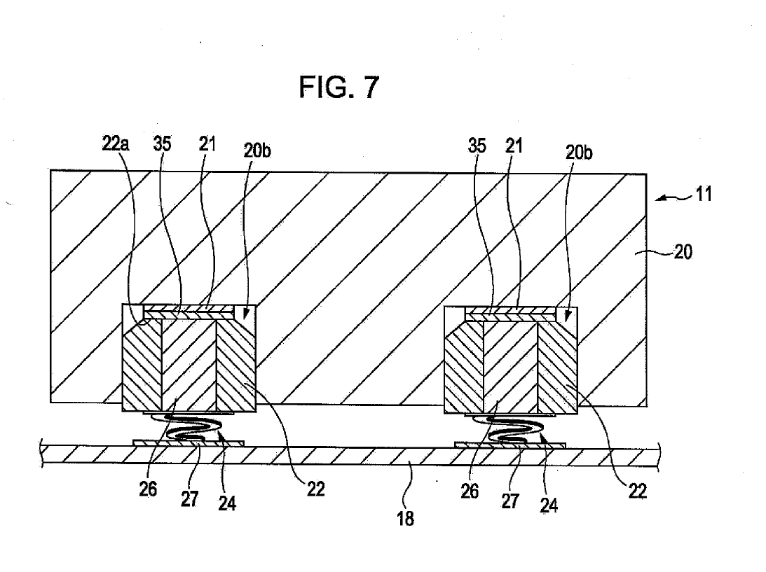

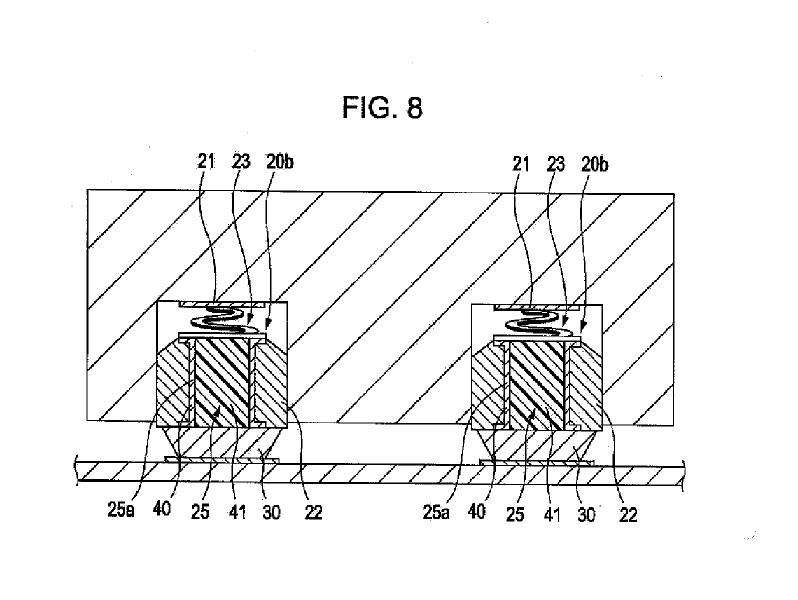

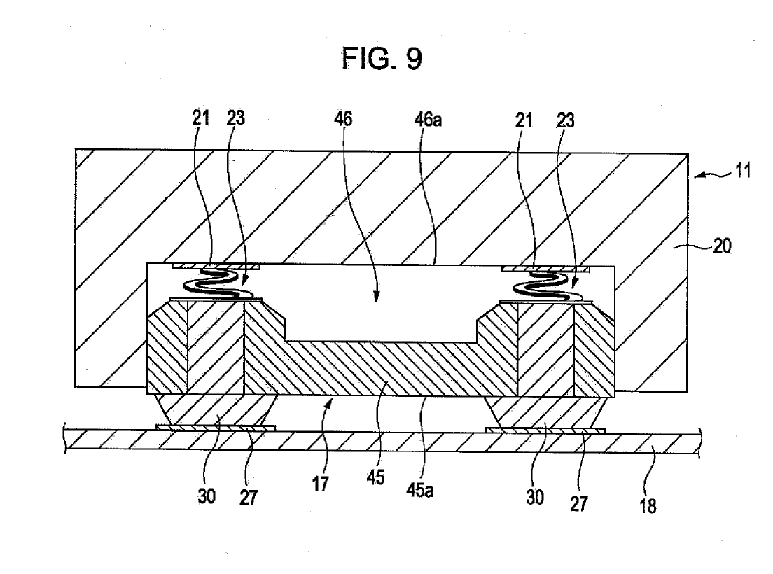

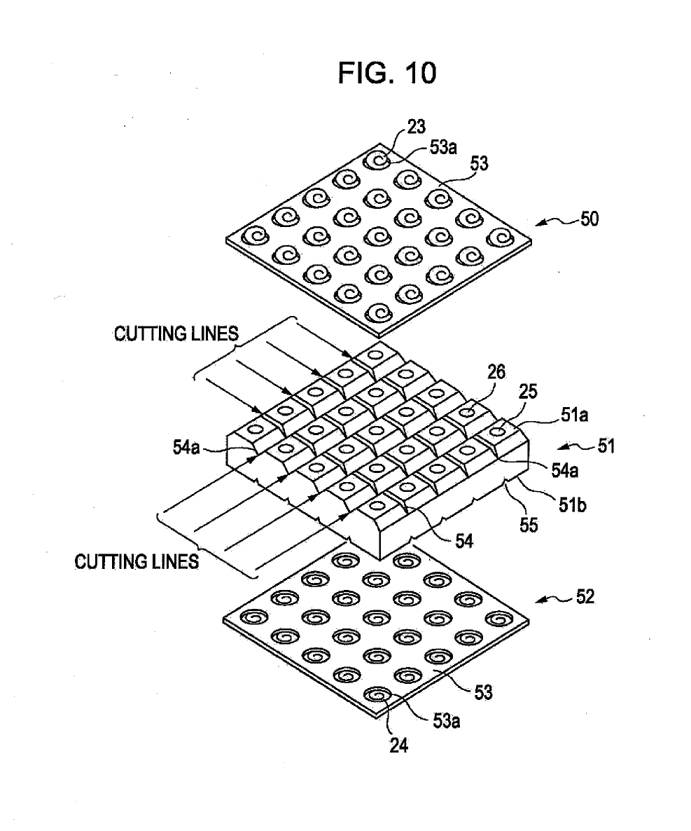

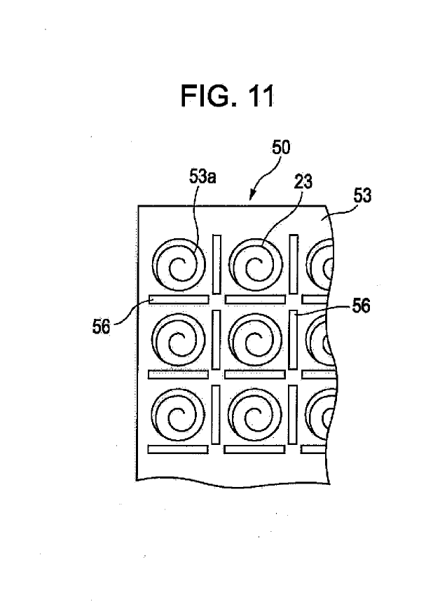

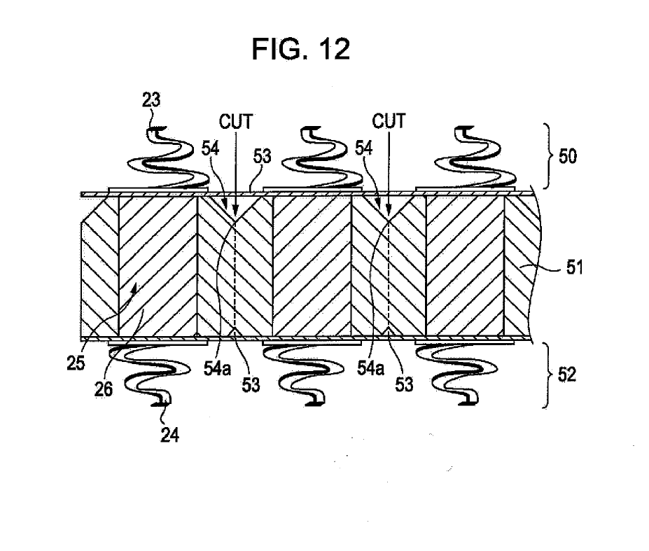

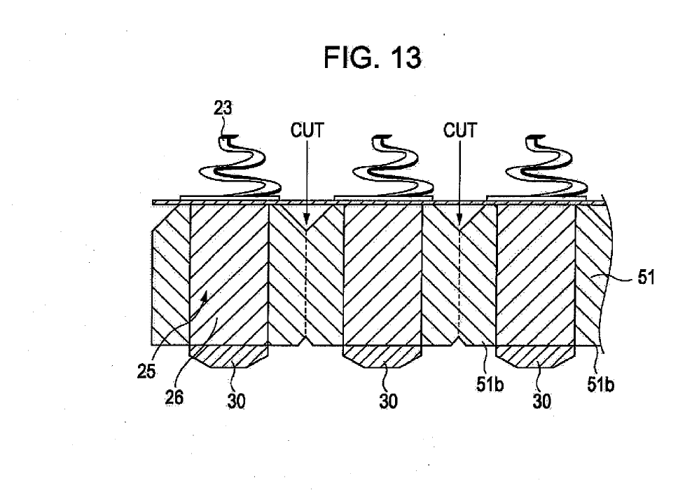

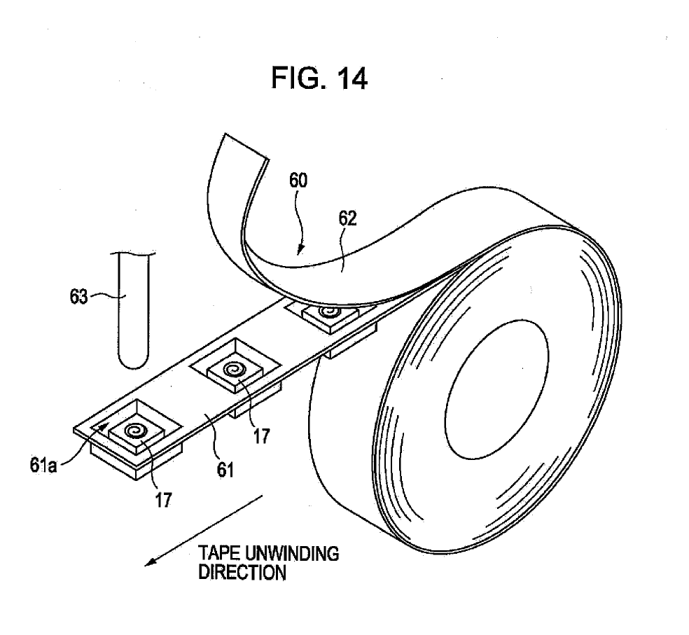

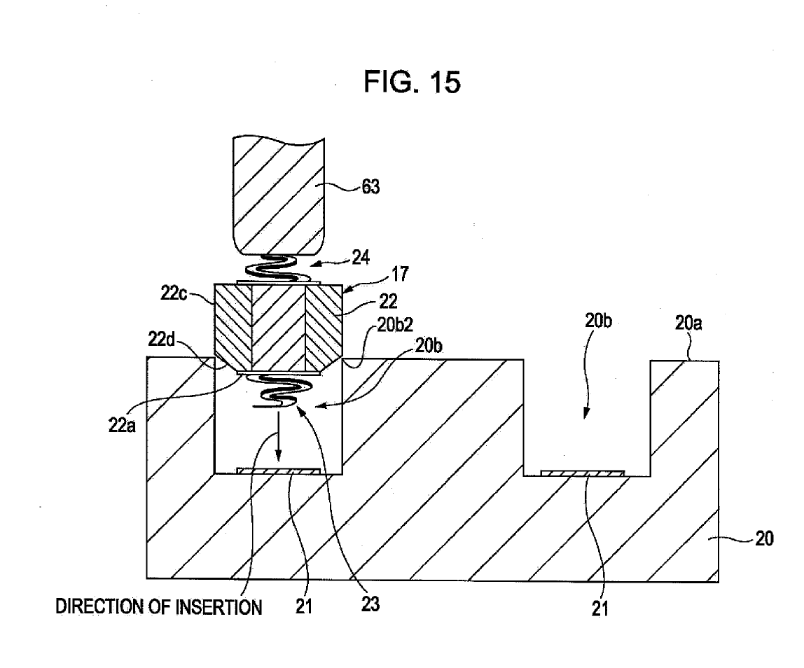

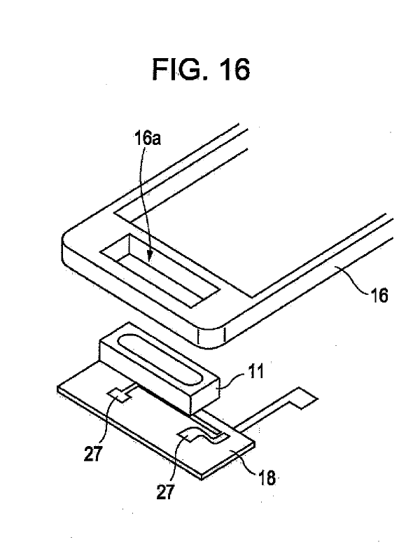

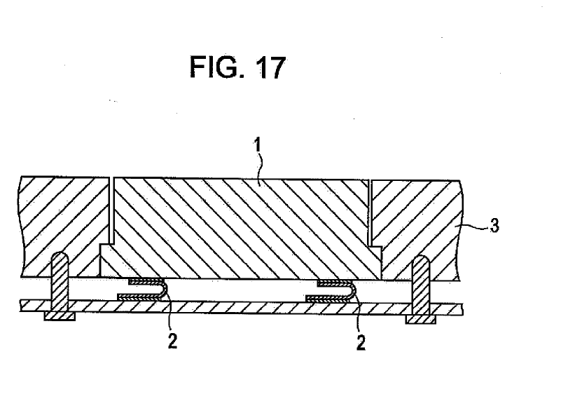

1. A function element comprising an element body and a terminal portion,
wherein the element body has a recess,
wherein the terminal portion includes a base, an element-side terminal fixed to the base and electrically connectable to the element body, and an electronic-device-side terminal fixed to the base and electrically connectable to an electronic device,
wherein at least one of the element-side terminal and the electronic-device-side terminal comprises a resiliently deformable terminal,
wherein the base is embedded in the recess so that the element-side terminal is electrically connected to the element body,
wherein in a state where the base is embedded in the recess, the base has an exposed surface which is a surface that is exposed on an outer surface of the element body, an insertion surface which is a surface that is positioned opposite to the exposed surface, and a side surface which is a surface that connects the insertion surface and the exposed surface, wherein the insertion surface and the side surface have a sloped surface therebetween, and wherein in an area where the sloped surface is provided, a width of the base increases gradually from the insertion surface towards the exposed surface, and
wherein the base has a through hole that extends between a surface of the base on which the element-side terminal is provided and another surface of the base on which the electronic-device-side terminal is provided, and wherein the element-side terminal and the electronic-device-side terminal are electrically connected to each other through a conductive member provided within the through hole.

2. The function element according to claim 1, wherein in a state where the base is embedded in the recess, the base has an exposed surface which is a surface that is exposed on an outer surface of the element body, an insertion surface which is a surface that is positioned opposite to the exposed surface, and a side surface which is a surface that connects the insertion surface and the exposed surface, wherein the element-side terminal is provided on the insertion surface, and wherein the electronic-device-side terminal is provided on the exposed surface.

3. The function element according to claim 1, wherein the element-side terminal comprises the resiliently deformable terminal.

4. The function element according to claim 1, wherein the element-side terminal and the electronic-device-side terminal both comprise the resiliently deformable terminals.

5. The function element according to claim 1, wherein the resiliently deformable terminal has a spiral shape such that the center of the spiral protrudes away from the base.

6.-7. (canceled)

8. The function element according to claim 1, wherein the element-side terminal and the electronic-device-side terminal respectively include a plurality of element-side terminals and a plurality of electronic-device-side terminals that are provided on the same base, and wherein the base is embedded in the recess so that the plurality of element-side terminals is electrically connected to the element body.

9. The function element according to claim 1, wherein the base is press-fitted to the recess.

10. The function element according to claim 1, wherein the function element comprises a speaker.

11. The function element according to claim 1, wherein the function element comprises a microphone.

12. An electronic device including an electrode that is electrically connected to the electronic-device-side terminal of the function element according to claim 1.

13. The electronic device according to claim 12, wherein the electronic-device-side terminal comprises the resiliently deformable terminal, the electronic-device-side terminal being pressed against the electrode of the electronic device so as to be electrically connected to the electrode.

14. The electronic device according to claim 12, wherein the electronic device comprises a portable telephone.

15. A method for manufacturing a function element that includes an element body and a terminal portion, the method comprising:
forming a recess in the element body;
setting an element-side terminal on an insertion surface of a base included in the terminal portion and setting an electronic-device-side terminal on a surface of the base that is opposite to the insertion surface, the insertion surface facing in a direction in which the base is to be inserted into the recess, at least one of the element-side terminal and the electronic-device-side terminal comprising a resiliently deformable terminal;
embedding the base into the recess with the insertion surface facing the recess so as to electrically connect the element-side terminal to the element body, the base having an exposed surface that is exposed on an outer surface of the element body; and
forming grooves along cuffing lines in the insertion surface of the substrate so that when the substrate is cut into the individual bases, sloped surfaces are formed between the insertion surfaces and side surfaces of the bases, the side surfaces connecting the insertion surfaces with the surfaces of the bases that are opposite to the insertion surfaces, the sloped surfaces being formed such that a width of each base increases gradually from the insertion surface thereof towards the surface opposite to the insertion surface,
wherein the base has a through hole that extends between a surface of the base on which the element-side terminal is provided and another surface of the base on which the electronic-device-side terminal is provided, and wherein the element-side terminal and the electronic-device-side terminal are electrically connected to each other through a conductive member provided within the through hole.

16. The method for manufacturing the function element according to claim 15, wherein the element-side terminal comprises the resiliently deformable terminal, and wherein the element-side terminal is resiliently deformed so that the element-side terminal is electrically connected to the element body.

17. The method for manufacturing the function element according to claim 15, wherein the element-side terminal and the electronic-device-side terminal both comprise the resiliently deformable terminals, and wherein the element-side terminal is resiliently deformed so that the element-side terminal is electrically connected to the element body.

18. The method for manufacturing the function element according to claim 16, wherein the base is press-fitted to the recess.

19. The method for manufacturing the function element according to claim 15, wherein a plurality of the element-side terminals is set on the insertion surface of a substrate having a plurality of the bases integrated therein, and a plurality of the electronic-device-side terminals is set on the surface of the substrate that is opposite to the insertion surface, and wherein the substrate is subsequently cut into the individual bases.

20. (canceled)

21. The method for manufacturing the function element according to claim 19, wherein the resiliently deformable terminal included in said at least one of the element-side terminal and the electronic-device-side terminal includes a plurality of resiliently deformable terminals, the plurality of resiliently deformable terminals being attached to a sheet member, and
wherein the sheet member is joined to the substrate, and the substrate and the sheet member are subsequently cut together into the individual bases.

22. The method for manufacturing the function element according to claim 21, wherein the substrate is cut into the individual bases after the sheet member is joined to the substrate and removed therefrom.

23. The method for manufacturing the function element according to claim 15, further comprising storing the terminal portion into a carrier tape, the terminal portion having the element-side terminal and the electronic-device-side terminal attached to the base of the terminal portion; extracting the terminal portion from the carrier tape while holding the terminal portion with a carrying member; and inserting the terminal portion into the recess of the element body.

24. A method for manufacturing an electronic device, comprising electrically connecting the electronic-device-side terminal of the function element manufactured on the basis of the method set forth in claim 15 to an electrode of the electronic device.

25. The method for manufacturing the electronic device according to claim 24, wherein the electronic-device-side terminal comprises the resiliently deformable terminal, the electronic-device-side terminal being pressed against the electrode of the electronic device so as to be electrically connected to the electrode.

26. The method for manufacturing the electronic device according to claim 24, wherein the electronic-device-side terminal and the electrode of the electronic device are joined to each other by soldering.
